(19) United States
(12) Patent Application Publication
(10) Pub. No.: US 2006/0046378 A1
(43) Pub. Date: Mar. 2, 2006

(54) Methods of fabricating MIM capacitor employing metal nitride layer as lower electrode

(75) Inventors: Jae-Hyoung Choi, Gyeonggi-do (KR); Young-Sun Kim, Gyeonggi-do (KR); Cha-Young Yoo, Gyeonggi-do (KR); Jung-Hee Chung, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/209,541

(22) Filed: Aug. 23, 2005

(30) Foreign Application Priority Data
Aug. 26, 2004 (KR) 10-2004-0067640
Jan. 5, 2005 (KR) 10-2005-0000996

(51) Int. Cl. H01L 21/8244

(52) U.S. Cl. 438/238

(57) ABSTRACT

There are provided methods of fabricating a metal-insulator-metal (MIM) capacitor employing a metal nitride layer as a lower electrode. The method includes forming an insulating layer on a semiconductor substrate. A metal source gas and a nitride gas are supplied to the insulating layer, thereby depositing a metal nitride. A flushing gas including nitrogen is supplied to the metal nitride to enhance nitridation reaction. Along with the supply of a metal source gas and a nitride gas, the operation of supplying a flushing gas is performed at least one time alternately and repeatedly, thereby forming a metal nitride layer.

### CROSS-REFERENCE TO RELATED APPLICATION

This application claims priority from Korean Patent Application Nos. 20054-0067640, filed Aug. 26, 2004 and 2005-0000996, filed Jan. 5, 2005, the disclosures of which are incorporated herein by reference in their entireties as if set forth fully herein.

### FIELD OF THE INVENTION

The present invention relates to a method of fabricating a semiconductor device, and more particularly, to a method of fabricating a metal-insulator-metal (MIM) capacitor.

### BACKGROUND OF THE INVENTION

A semiconductor memory device, particularly, a dynamic random access memory (DRAM) is a memory device for storing data in a capacitor of a unit cell. The unit cell of a DRAM is composed of one access transistor and one cell capacitor, which are connected in series.

A conventional cell capacitor utilizes a metal-insulator-silicon (MIS) structure. In a capacitor having an MIS structure, a storage electrode as a lower electrode uses a polysilicon electrode, and a plate electrode as an upper electrode uses a metal electrode. A dielectric layer is disposed between the storage electrode and the plate electrode. Unfortunately, an MIS structure can change the electrical characteristics of a device due to oxidation reaction that can occur at the interface between the polysilicon electrode and the dielectric layer. Further, a capacitor having an MIS structure can exhibit a nonuniform capacitance depending on the magnitude of a voltage applied to the metal plate electrode. For example, if the polysilicon storage node electrode is doped with n-type impurities, and a negative voltage is applied to the metal plate electrode, holes are induced on the surface of the polysilicon storage node electrode. That is, a depletion layer may be formed on the surface of the lower electrode, and the thickness of the depletion layer may be varied depending on the magnitude of the negative voltage. Because of this, the capacitance of the capacitor is not uniform, and is varied depending on the magnitude of the voltage applied to the electrodes. That is, the capacitor having an MIS structure is not suitable to being employed to a semiconductor device requiring characteristics of an elaborate structure.

Further, it can be difficult to increase a cell capacitance within a limited area in the case that a design rule of a DRAM device is reduced. In order to increase the cell capacitance, a height of a cell capacitor may be formed higher, and an equivalent oxide thickness (Toexq) of a dielectric layer may be reduced. In the case that the design rule is 100 nm or less, there is a limitation to increasing a height of the cell capacitor greater than 2.0 μm. Therefore, in order to implement a cell capacitor suitable to a highly integrated DRAM device, it is required to reduce the equivalent oxide thickness of the dielectric layer of the cell capacitor. In the capacitor having a conventional MIS structure, there is a limitation to forming a dielectric layer having an equivalent oxide thickness smaller than about 20 Å.

In order to solve the problems related to an MIS structure, a metal-insulator-metal (MIM) structure, in which an upper electrode and a lower electrode are all formed of metal layers, has been employed. In specific, a technology in which the lower electrode is formed of a titanium nitride (TiN) layer is used in an MIM capacitor. The lower electrode, which is formed of a titanium nitride layer, shows an excellent electrical reliability because the lower electrode has a low resistivity, and suppresses the generation of a parasitic capacitance. Further, since the titanium nitride layer has a strong oxidation resistance, it is suppressed that a native oxide layer is formed on the titanium nitride layer. Thus, it is easy to reduce the equivalent oxide thickness of the dielectric layer formed on the titanium nitride layer. For this reason, a titanium nitride layer has been widely used as the lower electrode.

However, when the titanium nitride layer replaces the polysilicon layer for the lower electrode, a contact resistance at the interface between the lower electrode, which is formed of the titanium nitride layer, and a polysilicon plug disposed thereunder is increased, thereby deteriorating the operation characteristics of a device. In order to improve the contact resistance, a titanium silicide (TiSi₂) layer as an ohmic contact layer may be formed on an upper surface of the polysilicon plug.

A method of forming the titanium silicide layer on an upper surface of the polysilicon plug, and then, forming the lower electrode using a metal layer is disclosed in Korean Patent Publication No. 2002-84596 entitled “Method of fabricating capacitor.”

According to Korean Patent Publication No. 2002-84596, an etch stop layer and a molding insulating layer are sequentially formed on a substrate having a polysilicon plug penetrating an interlayer insulating layer, and the molding insulating layer and the etch stop layer are patterned, thereby forming a capacitor hole exposing the polysilicon plug. A titanium layer is formed on an overall surface of the substrate having the capacitor hole, and concurrently, a titanium silicide layer is formed on the surface of the polysilicon plug. An unreacted titanium layer remaining on the surface of the molding insulating layer is removed, and the titanium silicide layer is exposed to ammonia (NH₃) plasma. As a result, a nitrified titanium silicide (Ti—Si—N) layer is formed on the surface of the titanium silicide layer. A titanium nitride layer and a sacrificial layer are sequentially formed on the substrate having the nitrified titanium silicide layer. The sacrificial layer and the titanium nitride layer are planarized, thereby forming a titanium nitride layer pattern, that is, lower electrode inside the capacitor hole. Then, the molding insulating layer and the sacrificial layer are removed, thereby exposing an inner wall and an outer sidewall of the lower electrode.

In the method of fabricating a capacitor according to Korean Patent Publication No. 2002-84596, while removing the molding insulating layer and the sacrificial layer to expose the inner wall and the outer sidewall of the lower electrode, an etch solution may penetrate into the interface between the lower electrode and the etch stop (Si₃N₄) layer, so as to further etch the interlayer insulating layer. As a result, a through hole may be formed in the interlayer insulating layer. Unfortunately, a through hole in the interlayer insulating layer may render a semiconductor device defective.

In the case where a titanium nitride layer is formed using a chemical vapor deposition (CVD) method, a throughput may be improved, but a through hole may be formed in the interlayer insulating layer as described above. Further, since the CVD TiN layer is formed by continuous reaction of a tetrachlorotitanium (TiCl₄) gas and an ammonia (NH₃) gas, a chlorine content in the CVD TiN layer may be increased. In this case, the chlorine atoms may cause a crack of the CVD TiN layer.

### SUMMARY OF THE INVENTION

Therefore, an embodiment of the present invention is directed to a method of forming a metal nitride layer for completely nitrifying an unreacted metal layer that remains after forming a metal silicide layer functioning as an ohmic contact layer, thereby preventing the generation of etch defects caused by the unreacted metal layer.

According to an embodiment of the present invention, a method is provided for fabricating an MIM capacitor wherein chlorine content is reduced in an electrode formed of a metal nitride layer, thereby improving productivity of devices incorporating same.

According to an embodiment of the present invention, a method of forming a metal nitride layer is provided that includes forming an insulating layer on a semiconductor substrate. A metal source gas and a nitride gas are supplied to the insulating layer, thereby depositing a metal nitride. A flushing gas including nitrogen is supplied to the metal nitride to enhance nitridation reaction. Alternately and repeatedly, the operations of supplying a metal source gas and a nitride gas, and supplying a flushing gas are performed at least one time. As a result, a metal nitride layer is formed on the insulating layer by a sequential flow deposition (SFD) method.

In accordance with embodiments of the present invention, the metal source gas may be a gas including titanium, tungsten, or tantalum. For example, the gas including titanium may be a tetrachlorotitanium (TiCl₄) gas.

According to embodiments of the present invention, the nitride gas may be a nitrogen gas or ammonia (NH₃) gas, and the flushing gas may be a nitrogen gas or ammonia (NH₃) gas.

In accordance with embodiments of the present invention, a purge gas may be supplied to the semiconductor substrate after the deposition of the metal nitride. Further, a purge gas may be supplied to the semiconductor substrate after the enhancement of nitridation reaction. The purge gas may be an inert gas, such as nitrogen.

In accordance with embodiments of the present invention, a metal nitride layer may be additionally formed on the SFD metal nitride layer using a chemical vapor deposition (CVD) process. The CVD metal nitride layer may be formed by continuous reaction of the metal source gas and the nitride gas without a supply of the flushing gas.

According to another embodiment of the present invention, a method of fabricating an MIM capacitor is provided that includes forming an interlayer insulating layer on a semiconductor substrate and forming a polysilicon contact plug that penetrates the interlayer insulating layer. A molding layer is formed on the contact plug and the interlayer insulating layer, and the molding layer is patterned, thereby forming a storage node hole exposing the contact plug. An ohmic contact layer is formed on an upper surface of the contact plug. A metal source gas and a nitride gas are supplied to the substrate having the ohmic contact layer, thereby depositing a metal nitride. A flushing gas including nitrogen is supplied to the substrate having the metal nitride, thereby enhancing nitridation reaction of a metal layer remaining in the lower portion of the metal nitride. Alternately and repeatedly, the operations of supplying a metal source gas and a nitride gas, and supplying a flushing gas are performed at least one time, thereby forming a lower electrode layer formed of a metal nitride layer. As a result, an SFD metal nitride layer is formed on the substrate having the ohmic contact layer.

In accordance with embodiments of the present invention, the operation of forming the ohmic contact layer may include forming a metal layer on the substrate having the storage node hole by deposition. The contact plug may react with the metal layer during the operation of forming the metal layer by deposition, thereby forming a metal silicide layer.

In accordance with embodiments of the present invention, the metal source gas may be a gas including titanium, tungsten, or tantalum. For example, the gas including titanium may be a tetrachlorotitanium (TiCl₄) gas, and the nitride gas may be an ammonia (NH₃) gas or a nitrogen gas. The metal nitride may be titanium nitride, and may be deposited with a thickness of 150 to 350 Å.

Further, the flushing gas may be an ammonia (NH₃) gas or a nitrogen (N₂) gas.

In accordance with embodiments of the present invention, after the operation of supplying a metal source gas and a nitride gas, a purge gas may be supplied. In addition, after the operation of supplying a flushing gas, a purge gas may be supplied. An exemplary purge gas is nitrogen.

In accordance with embodiments of the present invention, a metal nitride layer may be additionally formed on the SFD metal nitride layer, using a CVD process. The CVD metal nitride layer may be formed by continuous reaction of the metal source gas and the nitride gas without a supply of the flushing gas.

### BRIEF DESCRIPTION OF THE DRAWINGS

The above and other features and advantages of the present invention will become more apparent to those of ordinary skill in the art by describing in detail embodiments thereof with reference to the attached drawings in which:

FIGS. 1A through 1F are sectional views that illustrate formation processes sequentially in a method of fabricating an MIM capacitor according to embodiments of the present invention; and

FIG. 2 is a timing diagram that illustrates a process of forming a lower electrode in a method of fabricating an MIM capacitor according to embodiments of the present invention.

### DETAILED DESCRIPTION OF THE INVENTION

The present invention now is described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

Like numbers refer to like elements throughout. In the figures, the thickness of certain lines, layers, components, elements or features may be exaggerated for clarity. Broken lines illustrate optional features or operations unless specified otherwise. All publications, patent applications, patents, and other references mentioned herein are incorporated herein by reference in their entireties.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. As used herein, phrases such as “between X and Y” and “between about X and Y” should be interpreted to include X and Y. As used herein, phrases such as “between about X and Y” mean “between about X and about Y.” As used herein, phrases such as “from about X to Y” mean “from about X to about Y.”

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is inverted, elements described as “under” or “beneath” other elements or features would then be oriented “over” the other elements or features. Thus, the exemplary term “under” can encompass both an orientation of “over” and “under”. The device may be otherwise oriented (rotated 90 degrees or at other orientations) and the spatially relative descriptors used herein interpreted accordingly. Similarly, the terms “upwardly”, “downwardly”, “vertical”, “horizontal” and the like are used herein for the purpose of explanation only unless specifically indicated otherwise.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a “first” element, component, region, layer or section discussed below could also be termed a “second” element, component, region, layer or section without departing from the teachings of the present invention. The sequence of operations (or steps) is not limited to the order presented in the claims or figures unless specifically indicated otherwise.

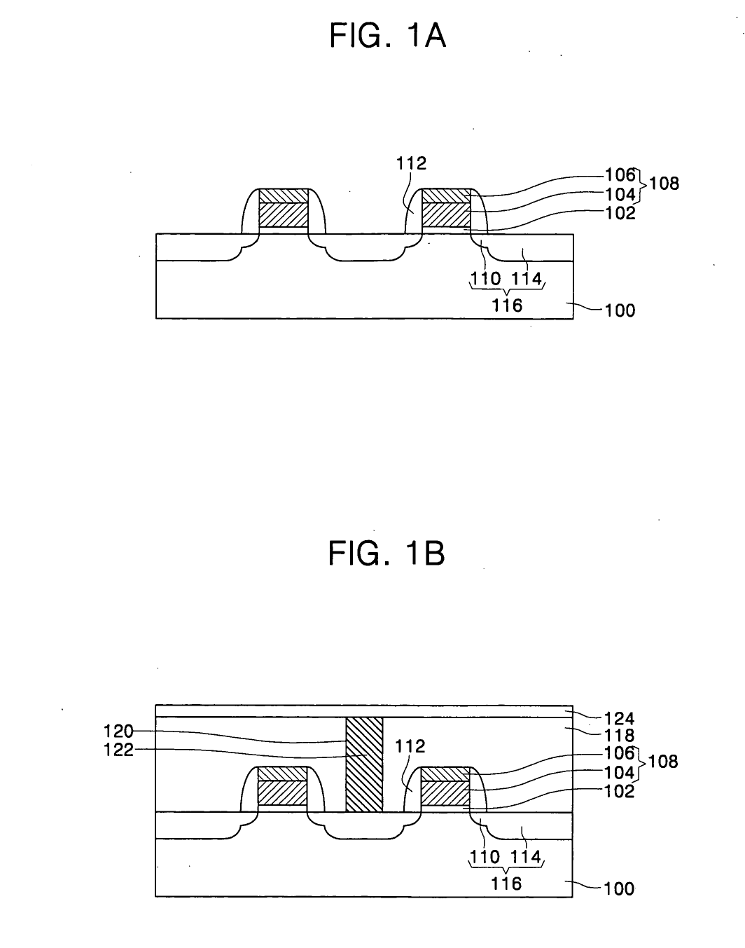

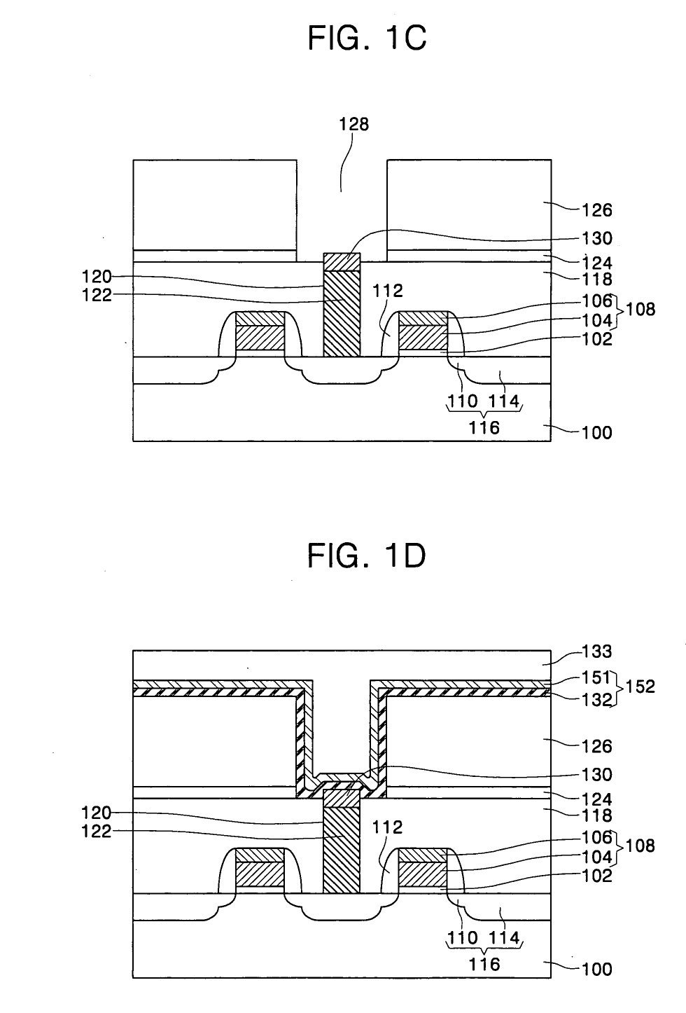

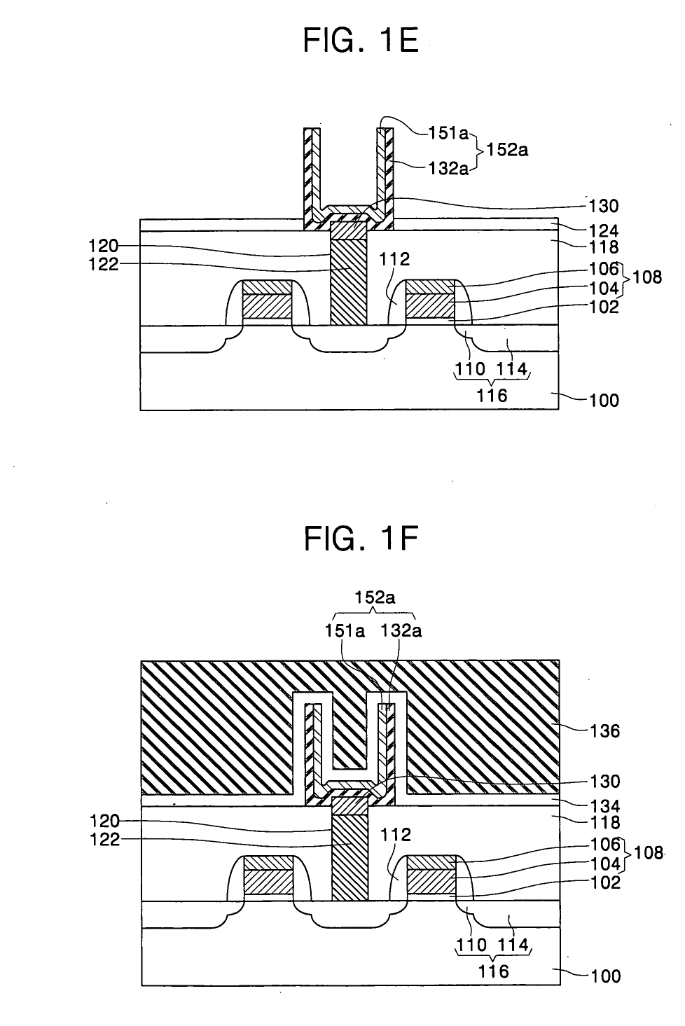

Referring to FIG. 1A, an isolation layer (not shown) is formed in a semiconductor substrate 100. The isolation layer may be formed using a typical shallow trench isolation (STI) process, and an active region is defined by the isolation layer, as would be understood by one skilled in the art. A gate insulating layer 102 and a gate conductive layer are sequentially formed on the semiconductor substrate having the isolation layer formed therein. The gate conductive layer may be formed of a refractory metal polycide layer. The gate conductive layer may be formed by sequentially stacking a polysilicon layer and a tungsten silicide layer. The gate conductive layer is patterned, thereby forming a gate electrode 108. As a result, the gate electrode 108 may include a polysilicon pattern 104 and a tungsten silicide pattern 106, which are sequentially stacked.

Using the gate electrode 108 as an ion implantation mask, impurity ions are implanted into the active region, thereby forming low density impurity regions 110. Insulating layer spacers 112 are formed on the sidewalls of the gate electrode 108 using a typical method, as would be understood by one skilled in the art. Using the insulating layer spacers 112 and the gate electrode 108 as ion implantation masks, impurity ions are implanted into the active region, thereby forming high density impurity regions 114 having a higher density than that of the low density impurity regions 110. The low density impurity regions 110 and the high density impurity regions 114 constitute LDD-type source/drain regions 116. The source/drain regions 116 and the gate electrode 108 constitute a MOS transistor.

Referring to FIG. 1B, an interlayer insulating layer 118 is formed on the substrate having the source/drain regions 116. The interlayer insulating layer 118 is patterned, thereby forming a contact hole 120 exposing any one of the source/drain regions 116. A conductive layer is formed on the interlayer insulating layer 118 to fill the contact hole 120. The conductive layer is planarized using a chemical mechanical polishing (CMP) process to expose an upper surface of the interlayer insulating layer 118. As a result, a contact plug 122 is formed inside the contact hole 120. The contact plug 122 may be formed of a polysilicon layer.

An etch stop layer 124 is formed on the contact plug 122 and the interlayer insulating layer 118. The etch stop layer 124 may be a silicon oxynitride (SiON) layer or silicon nitride (SiN) layer, for example.

Referring to FIG. 1C, a molding layer 126 is formed on the etch stop layer 124, and is preferably formed of a material having an etch selectivity with respect the etch stop layer 124. For example, the molding layer 126 may be formed of a plasma enhanced tetraethylorthosilicate (PE-TEOS) oxide layer, or a silicon oxide layer such as a BPSG layer or PSG layer. The molding layer 126 and the etch stop layer 124 are patterned, thereby forming a storage node hole 128 exposing the contact plug 122.

A titanium layer is formed on the substrate having the storage node hole 128. The titanium layer may be formed with a thickness of about 85 Å, using a chemical vapor deposition (CVD) method. During the deposition of the titanium layer, a titanium silicide layer 130 may be formed on a surface of the contact plug 122. The titanium silicide layer 130 is formed by the reaction of the titanium layer and the contact plug 122. The titanium silicide layer 130 functions as an ohmic contact layer to improve contact resistance between the contact plug 122 and a lower electrode to be formed in a subsequent process. The titanium silicide layer 130 may be formed by the thermal processing performed in an ammonia plasma (NH₃ plasma) atmosphere after the titanium layer is formed. During the thermal processing, the unreacted titanium layer that remains on a surface of the molding layer may be nitrified.

Referring to FIG. 1D, a lower electrode layer 152 is formed on the semiconductor substrate having the titanium silicide layer 130. The lower electrode layer 152 may be formed of a metal nitride layer, for example, a titanium nitride layer, a tantalum nitride layer, or a tungsten nitride layer. The lower electrode layer 152 may be formed by sequentially stacking a first lower electrode layer 132 and a second lower electrode layer 151. The first lower electrode layer 132 may be formed using a sequential flow deposition (SFD) method, and the second lower electrode layer 151 may be formed using a CVD method. A total thickness of the first and second lower electrodes 132, 151 may be formed in a range of 200 to 300 Å. For example, the first lower electrode layer 132 may be formed with a thickness of 70 to 200 Å, and the second lower electrode 151 layer may be formed with a thickness of 70 to 200 Å. Alternatively, the lower electrode layer 152 may be formed of only the first lower electrode layer 132. That is, the second lower electrode layer 151 may be omitted. In this case, the first lower electrode layer 132 may be formed with a thickness of 150 to 350 Å.

The CVD process for forming the second lower electrode layer 151 may be sequentially performed inside a chamber where the SFD process is performed to form the first lower electrode layer 132. That is, the first and second lower electrode layers 132, 151 may be formed in an in-situ manner. Further, the first and second lower electrode layers 132, 151 may be formed at substantially the same temperature. Alternatively, the first and second lower electrode layers 132, 151 may be formed in two different chambers separately. However, the first and second lower electrode layers 132, 151 are preferably formed using the in-situ manner in the point of a throughput. After the lower electrode layer 152 is formed, the unreacted metal layer that remains on a surface of the molding layer 126 (for example, unreacted titanium layer) may be removed using a typical wet etch process, as would be understood by one skilled in the art. The titanium layer that remains after the wet etch process is performed may be plasma-treated using a gas including nitrogen. The nitrogen plasma processing may be performed using NH₃ gas or N₂ gas for about 80 seconds, for example. A sacrificial layer 133 is formed on the lower electrode layer 152 to fill the storage node hole 128. The sacrificial layer 133 may be formed of the same material layer as the molding layer 126.

In another embodiment of the present invention, the titanium layer for forming the titanium silicide layer 130, and the metal nitride layer for forming the lower electrode layer 152 may be sequentially formed in an in-situ manner.

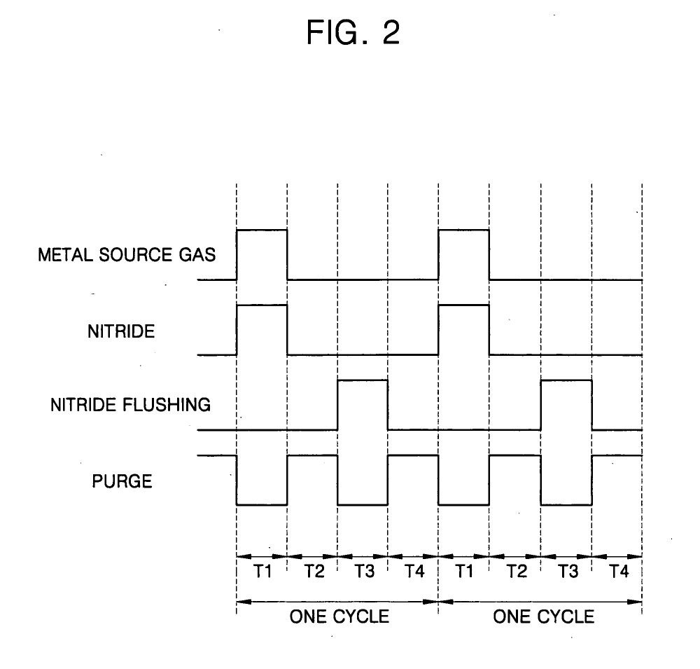

The first lower electrode layer 132 may be formed of a titanium nitride layer using the SFD method. In this case, a process of forming the first lower electrode layer 132 will be explained in detail with reference to a timing diagram of FIG. 2.

First, a semiconductor substrate having the titanium silicide layer 130 is loaded into a process chamber. A metal source gas and a nitride gas are supplied into the process chamber in which the semiconductor substrate is loaded for about one hour (T1), for example, thereby forming a metal nitride on the semiconductor substrate by deposition (first step). The metal source gas uses TiCl₄, and is supplied at a flow rate of 5 to 50 sccm, for example. The nitride gas may use NH₃ or N₂ gas. The nitride gas may be supplied at a flow rate of 10 to 50 sccm, for example. While the metal source gas and the nitride gas are supplied, the inside of the process chamber can be maintained with a pressure of 1 to 5 torr and at a temperature of 550 to 800° C., for example. Thus, a titanium nitride (the metal nitride) is deposited on the inner wall of the storage node holes 128 and on the upper surface of the molding layer 126.

Then, the metal source gas and the nitride gas that remains inside the process chamber with an unreacted layer can be purged for about two hours (T2) (second step), for example. The purge process may be performed using an inert gas, for example, nitrogen (N₂) gas.

After the purge process, a gas such as ammonia (NH₃) is supplied into the process chamber for about three hours (T3) to perform a nitridation flushing process (third step). The nitridation flushing process is preferably performed for at least 5 seconds. The inner temperature of the process chamber during the nitridation flushing process may be between about 500 to 650° C., for example. The nitridation flushing process may be performed in an in-situ manner at the same temperature as that of the process in the first step.

After the titanium silicide layer 130 is formed, even though an unreacted titanium layer remains on the inner wall of the storage node hole 128, the unreacted titanium layer may be nitrified by the nitridation flushing process. After the nitridation flushing process, the nitride gas that remains inside the process chamber can be purged for about four hours (T4) (fourth step), for example.

One process cycle which is composed of the first through fourth steps described above is repeatedly performed at least twice. This is intended to repeatedly perform the nitridation flushing process while the titanium nitride layer is formed, and to completely nitrify the unreacted titanium layer that remains inside the storage node hole. The one process cycle may be performed for about 10 seconds, for example. During the one process cycle, the titanium nitride layer may be formed with a thickness of 20 to 25 Å, for example. At least one purge process in the purge processes (second and fourth steps) may be omitted during the one process cycle.

As a result, when at least the first lower electrode layer 132 is formed by repeatedly performing the one process cycle, the titanium layer that remains on the surface of the molding layer can be completely nitrified. Thus, it can prevent the generation of etch defects caused by a wet etch solution during the removal of the molding layer and a sacrificial layer in a subsequent process. Furthermore, in the case that at least the first lower electrode layer 132 is formed by the SFD method, a chlorine content of the lower electrode layer 152 including the first lower electrode layer 132 can be minimized. Thus, it can prevent the generation of crack of the lower electrode layer 152.

In still another embodiment of the present invention, the first lower electrode layer 132 may be formed using an atomic layer deposition (ALD) method. While the first lower electrode layer 132 is formed using the ALD method, the nitridation flushing process is repeatedly performed at least twice.

The CVD process for forming the second lower electrode layer 151 may be performed by a continuous reaction of the metal source gas and the nitride gas without using the flushing gas. Therefore, when the lower electrode layer 152 is formed by sequentially stacking the first and second lower electrode layers 132, 151, a production yield can be improved in comparison with the case where the lower electrode layer 152 is formed of only the first lower electrode layer 132.

According to the embodiments of the present invention, while the lower electrode layer (metal nitride layer) 152 is formed, the nitridation flushing process is repeatedly performed at least twice. As a result, the titanium layer that remains inside the storage node hole 128 can be effectively nitrified.

Referring to FIG. 1E, the sacrificial layer 133 (FIG. 1D) and the lower electrode layer 152 (FIG. 1D) are planarized using a CMP process or a dry etch back process, thereby exposing an upper surface of the molding layer 126. As a result, a storage node isolated inside the storage node hole 128, that is, a lower electrode 152a is formed, as illustrated. Further, a sacrificial layer pattern (not shown) may remain inside a space surrounded by the lower electrode 152a, as would be understood by one skilled in the art.

In the case that the lower electrode layer 152 is formed by sequentially stacking the first and second lower electrode layers 132, 151, the lower electrode 152a may be formed to include a first lower electrode 132a and a second lower electrode 151a surrounding the inner wall of the first lower electrode 132a. Alternatively, in the case that the second lower electrode layer 151 is omitted, the lower electrode 152a may be formed of only the first lower electrode 132a.

After the lower electrode 152a is formed, the molding layer and the sacrificial layer pattern are removed, thereby exposing an inner wall and an outer sidewall of the lower electrode 152a. The molding layer and the sacrificial layer pattern may be removed using a wet etch solution such as fluoric acid solution. While the molding layer is removed, the wet etch solution may not penetrate into the interlayer insulating layer 118. This is because a titanium layer does not exist at the interface between the first lower electrode 132a and the etch stop layer 124. Thus, it can prevent the generation of etch defects inside the interlayer insulating layer 118.

Referring to FIG. 1F, a dielectric layer 134 and an upper electrode 136 are sequentially formed on the semiconductor substrate from which the molding layer is removed, so as to cover the surface of the lower electrode 152a. Before the dielectric layer 134 is formed, the etch stop layer 124 may be selectively removed. The dielectric layer 134 may be formed of a high-k dielectric layer such as a hafnium oxide (HfO₂) layer, an aluminum oxide (Al₂O₃) layer, a tantalum oxide (Ta₃O₅) layer, a lanthanum oxide (La₂O₃) layer, or a zirconium oxide (ZrO₂) layer. In order to improve the characteristics of the dielectric layer 134, the dielectric layer 134 may be thermally processed, or plasma-treated. The upper electrode 136 may be formed of a metal layer such as a titanium layer, a tungsten layer, a tantalum layer, a titanium nitride layer, a tungsten nitride layer, or a tantalum nitride layer, for example.

As described above, according to embodiments of the present invention, a nitridation flushing process is repeatedly performed at least twice during the process of forming the metal nitride layer as the lower electrode layer covering the inner wall of the storage node hole penetrating the molding layer. As a result, an unreacted metal layer can be completely nitrified during the nitridation flushing process even though the unreacted metal layer exists inside the storage node hole. Therefore, during the process of removing the molding layer using a wet etch solution, the wet etch solution is prevented from penetrating into the interlayer insulating layer via the interface between the lower electrode and the etch stop layer.

Further, according to embodiments of the present invention, the lower electrode layer can be formed at least using an SFD process and a CVD process. Therefore, the lower electrode layer can be prevented from becoming cracked, thereby improving productivity of a semiconductor device incorporating the lower electrode.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. The invention is defined by the following claims, with equivalents of the claims to be included therein.

What is claimed is:

1. A method of forming a metal nitride layer comprising:
forming an insulating layer on a semiconductor substrate;
supplying a metal source gas and a nitride gas on the insulating layer, such that metal nitride is deposited thereon;
supplying a flushing gas including nitrogen on the metal nitride to enhance nitridation reaction; and
alternately and repeatedly performing the operations of supplying a metal source gas and a nitride gas, and supplying a flushing gas at least one time, to form a first metal nitride layer.

2. The method according to claim 1, wherein the metal source gas comprises titanium, tungsten, or tantalum.

3. The method according to claim 2, wherein the metal source gas comprises tetrachlorotitanium (TiCl₄) gas.

4. The method according to claim 1, wherein the nitride gas comprises nitrogen gas or ammonia (NH₃) gas.

5. The method according to claim 1, wherein the flushing gas comprises nitrogen gas or ammonia (NH₃) gas.

6. The method according to claim 1, further comprising:
supplying a purge gas on the semiconductor substrate after the deposition of the metal nitride; and
supplying a purge gas on the semiconductor substrate after the enhancement of nitridation reaction.

7. The method according to claim 6, wherein the purge gas comprises an inert gas.

8. The method according to claim 7, wherein the inert gas comprises a nitrogen gas.

9. The method according to claim 1, further comprising forming a second metal nitride layer on the first metal nitride layer using a chemical vapor deposition (CVD) process, wherein the CVD process is performed by continuously supplying a metal source gas and a nitride gas without a supply of a flushing gas.

10. A method of fabricating an MIM capacitor comprising:
forming an interlayer insulating layer on a semiconductor substrate;
forming a polysilicon contact plug penetrating the interlayer insulating layer;
forming a molding layer on the contact plug and the interlayer insulating layer;
patterning the molding layer to form a storage node hole that exposes the contact plug;
forming an ohmic contact layer on an upper surface of the contact plug;
supplying a metal source gas and a nitride gas on the substrate having the ohmic contact layer to deposit a metal nitride;
supplying a flushing gas including nitrogen on the substrate having the metal nitride to enhance nitridation reaction of a metal layer that remains in a lower portion of the metal nitride; and
alternately and repeatedly performing the operations of supplying a metal source gas and a nitride gas, and supplying a flushing gas at least one time to form a first lower electrode layer of metal nitride.

11. The method according to claim 10, wherein the operation of forming an ohmic contact layer comprises forming a metal layer on the substrate having the storage node hole by deposition.

12. The method according to claim 11, wherein the contact plug reacts with the metal layer during the operation of forming a metal layer by deposition to form a metal silicide layer.

13. The method according to claim 12, further comprising removing an unreacted metal layer that remains on a surface of the interlayer insulating layer and the molding layer after the operation of forming a metal silicide layer.

14. The method according to claim 10, wherein the metal source gas comprises titanium, tungsten, or tantalum.

15. The method according to claim 14, wherein the metal source gas comprises tetrachlorotitanium (TiCl₄) gas, and the nitride gas comprises ammonia (NH₃) gas or nitrogen gas.

16. The method according to claim 15, wherein the metal nitride comprises titanium nitride, and a total thickness of the titanium nitride is in a range of 150 to 350 Å.

17. The method according to claim 10, wherein the flushing gas comprises ammonia (NH₃) gas or nitrogen (N₂) gas.

18. The method according to claim 15, wherein the tetrachlorotitanium (TiCl₄) gas is supplied at a flow rate of 5 to 50 sccm.

19. The method according to claim 10, wherein the nitride gas is supplied at a flow rate of 10 to 50 sccm.

20. The method according to claim 15, wherein the tetrachlorotitanium (TiCl₄) gas and the ammonia (NH₃) gas are supplied with a pressure of 1 to 5 torr and at a temperature of 550 to 800° C.

21. The method according to claim 10, further comprising:
supplying a purge gas after the operation of supplying a metal source gas and a nitride gas; and
supplying a purge gas after the operation of supplying a flushing gas.

22. The method according to claim 21, wherein the purge gas comprises nitrogen gas.

23. The method according to claim 10, further comprising:
forming a sacrificial layer on the first lower electrode layer;
planarizing the sacrificial layer and the first lower electrode layer until an upper surface of the molding layer is exposed to form a lower electrode that covers an inner wall of the storage node hole, and a sacrificial layer pattern that remains inside the lower electrode;
removing the sacrificial layer pattern and the molding layer; and
sequentially forming a dielectric layer and an upper electrode on the lower electrode.

24. The method according to claim 10, further comprising:
forming a second lower electrode layer on the first lower electrode layer using a CVD process, the CVD process being performed by continuously supplying the metal source gas and the nitride gas without a supply of the flushing gas;
forming a sacrificial layer on the second lower electrode layer;
planarizing the sacrificial layer, the second lower electrode layer, and the first lower electrode layer until an upper surface of the molding layer is exposed to form a lower electrode that covers an inner wall of the storage node hole, and a sacrificial layer pattern that remains inside the lower electrode;
removing the sacrificial layer pattern and the molding layer; and
sequentially forming a dielectric layer and an upper electrode on the lower electrode.

25. The method according to claim 24, wherein the first and second lower electrode layers are formed in-situ.

26. The method according to claim 24, wherein the first and second lower electrode layers are formed of titanium nitride layers.

27. The method according to claim 26, wherein the first lower electrode layer is formed with a thickness of 70 to 200 Å, and the second lower electrode layer is formed with a thickness of 70 to 200 Å.
